(19) United States
(12) Patent Application Publication
(10) Pub. No.: US 2007/0153951 A1
(43) Pub. Date: Jul. 5, 2007

(54) Phase interpolation for phase-locked loops

(76) Inventors: Chee How Lim, Beaverton, OR (US); Guneet Singh, Santa Clara, CA (US); Hendra Rustam, Santa Clara, CA (US)

Correspondence Address: Lee & Hayes, PLLC;c/o PortfolioIP, P.O. Box 52050, Minneapolis, MN, 55402, US

(21) Appl. No.: 11/321,407

(22) Filed: Dec. 29, 2005

(51) Int. Cl. H03D 3/24

(52) U.S. Cl. 375/376

(57) ABSTRACT

Embodiments of a phase interpolator for a phase-locked loop are presented herein.

### BACKGROUND

Phase-locked loops are generally implemented using integrated circuits and may be utilized for a variety of purposes. For example, phase-locked loops may be utilized for frequency control in interfaces, such as serial interfaces and so on. However, sources of signals processed by the phase-locked loops may introduce jitter, which increases uncertainty of the signal being processed and therefore may render the phase-locked loops unsuitable for their intended purpose.

### BRIEF DESCRIPTION OF THE DRAWINGS

FIG. 1 is an illustration of an exemplary implementation of a computing that is operable to employ phase interpolation techniques.

FIG. 2 is an illustration of an exemplary implementation of a system showing a phase interpolator and a phase-locked loop of FIG. 1 in greater detail.

FIG. 3 is an illustration of an exemplary implementation showing a self-biased second order phase-locked loop model that incorporates a phase interporlator.

FIG. 4 is an illustration of an exemplary schematic implementation showing the phase interpolator of FIG. 2 in greater detail.

FIG. 5 is a flow diagram depicting a procedure in an exemplary implementation in which an input reference clock signal and a feedback signal are mixed to reduce bandwidth of a phase-locked loop.

The same reference numbers are utilized in instances in the discussion to reference like structures and components.

### DETAILED DESCRIPTION

In the following discussion, exemplary devices are described which may provide and/or utilize phase interpolation for a phase-locked loops. Exemplary procedures are then described which may be employed by the exemplary devices, as well as by other devices.

Exemplary Devices

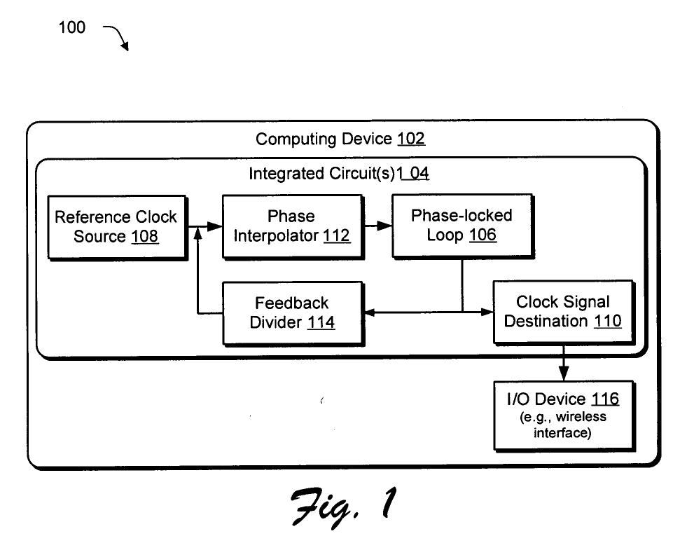

FIG. 1 illustrates an exemplary implementation 100 of a computing device 102 that is operable to employ phase interpolation techniques. The computing device 102 may be configured in a variety of ways. For example, the computing device 102 may be configured as a desktop personal computer (PC), a notebook computer, a wireless phone, a server, a wireless base station, as local area network (LAN) equipment, a network access device (e.g., a broadband access device), a personal digital assistant (PDA), and so on.

The computing device 102 is illustrated as including one or more integrated circuits 104, at least a portion of which are configured to provide a phase-locked loop 106. The phase-locked loop (PLL) 106 may be utilized for a variety of purposes. For example, the PLL 106 may be configured to phase align a reference clock source 108 with a clock signal destination 110, such as to align an internal core clock with a bus clock. The integrated circuit(s) 104, for instance, may include circuits which operate at a frequency that is “higher” relative to a frequency, at which, other circuits of the integrated circuits 104 operate. Therefore, the PLL 106 is operable to enable data to be exchanged between these circuits by phase synchronizing respective clocks.

However, in high-speed-serial interfaces (e.g., Peripheral Component Interconnect Express (PCIe), fully buffered dual in-line memory modules (FBD2), and so on), jitter may be accumulated on input/output transmit clocks (e.g., the clock signal destination 110) due to signals from an input reference clock (e.g., the reference clock source 108), thereby resulting in uncertainty of a signal being processed by the PLL 106. Jitter may be thought of as unwanted variations in frequency, phase and so on of a signal.

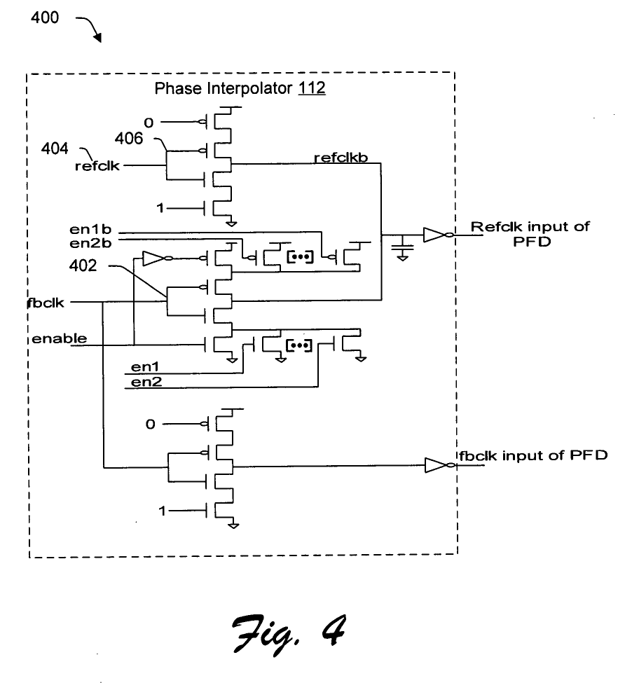

In order to reduce short term accumulated jitter, the bandwidth of the PLL 106 may be reduced through use of a phase interpolator 112. The phase interpolator 112, for instance, may utilize a phase mixing technique to reduce bandwidth of the PLL 106, and thereby reduce jitter. The phase interpolator 112 may be implemented in a wide variety of ways, such as a digital phase interpolator, further discussion of which may be found in relation to FIG. 4.

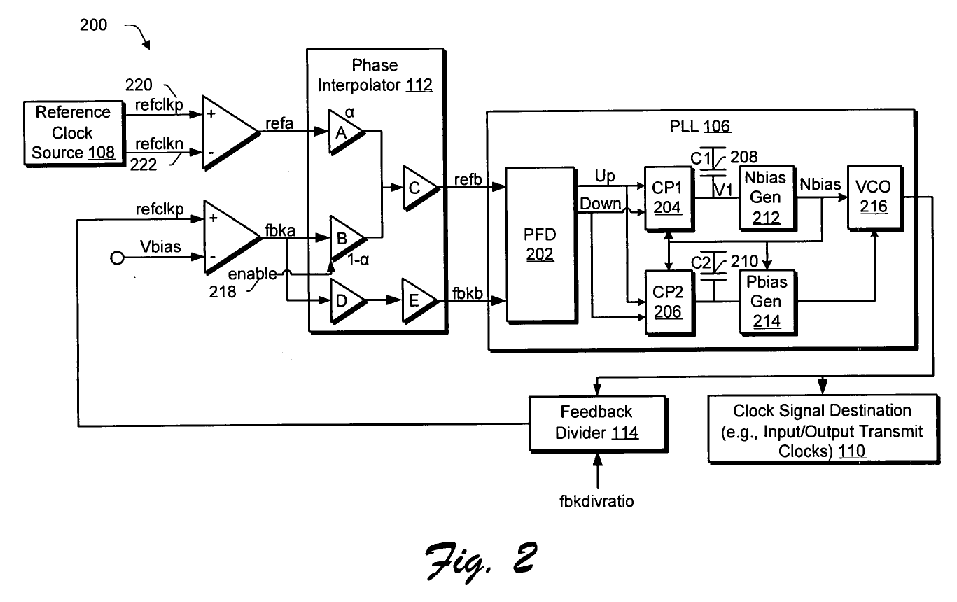

The integrated circuit(s) 104 of the computing device 102 are further illustrated as including a feedback divider 114. The feedback divider 114 is operable to further control operation of the PLL, further discussion of which may be found in relation to FIG. 2.

As previously described, the phase-locked loop 106 and the phase interpolator 112 may be used for a variety of purposes. For example, the output of the phase-locked loop 106 may be provided to an input/output (I/O) device 116 (e.g., a wireless interface, memory, and so on) via the clock signal destination 110. For instance, the I/O device 116 may be communicatively coupled to the phase-locked loop 106 (e.g., to align an internal core clock with a bus clock) such that communication may be performed between one or more of the integrated circuit(s) 104 and the I/O device 116. A variety of other instances are also contemplated.

FIG. 2 illustrates an exemplary implementation of a system 200 showing the phase interpolator 112 and PLL 106 of FIG. 1 in greater detail. The PLL 106 is implemented as a negative feedback system that includes a phase frequency detector (PFD) 202; first and second charge pumps (CP1, CP2) 204, 206; first and second capacitors (C1, C2) 208, 210; an Nbias generator 212; a Pbias generator 214; and a voltage controlled oscillator (VCO) 216.

The PFD 202 compares two input frequencies, illustrated as “refb” and “fbkb” in FIG. 2 that denote, respectively, a reference signal and a feedback signal. The PFD 202 is operable to generate an output that is a measure of a phase difference of the two input frequencies, which are illustrated as “up” and “down” which represents differences in respective edges of the input signals. For example, differences in the relative numbers of “up” or “down” pulses output by the PFD 202 indicate whether the reference signal has a frequency that is higher or lower than the feedback frequency.

These outputs are provided to respective charge pumps (CP1, CP2) 204, 206 which charge respective capacitors (C1, C2) 208, 210 according to the pulses. The Nbias generator 212 and Pbias generator 214 may then use the charge from these capacitors (C1, C2) 208, 210 to control voltage provided to the VCO 216, and therefore control the output frequency of the VCO 216. The output of the VCO 216 is provided to the clock signal destination 110, as well as the feedback divider 114. The feedback divider 114 divides the output of the VCO 216 by a feedback divider ratio (illustrated as “fbkdivratio”), a result of which is then provided back to the PFD 202 for further comparison. For example, the feedback divider ratio may be set at 10 to 1 where the VCO 216 generates a frequency that is ten times greater than the reference signal of the reference clock source 108, i.e., “refb” in FIG. 2. In another example, the feedback divider ratio of the feedback divider 114 may also be set at 1 to 10 where the VCO 216 operates at a frequency that is ten times less than the frequency of the reference signal of the reference clock source 108. A variety of other ratios are also contemplated. Thus, the PLL 106 provides a closed-loop system that can “lock” to a difference in frequencies and compensate for this difference accordingly.

As previously described, short-term accumulated jitter may be encountered on traditional high-speed interfaces due to an input reference clock, e.g., the reference clock source 108. Therefore, the system 200 may employ a phase interpolator 112 which utilizes phase mixing techniques to reduce PLL bandwidth and thereby reduce short-term accumulated jitter.

The phase interpolator 112 may be implemented in a variety of ways. For example, the phase interpolator 112 in FIG. 2 is illustrated as a phase mixer circuit having a plurality of buffers, depicted as “A”, “B”, “C”, “D” and “E”. The phase interpolator 112 may operate as follows. Initially, buffer “B” in FIG. 2 is disabled using an “enable” signal 218. The enable signal 218 may be implemented in a variety of ways. For example, the enable signal 218 may be implemented using a “sticky₁₃ lock” signal, which is a lock signal that stays “high” after the PLL 106 has locked and is independent of a current state of a lock signal of the PLL 106.

The PLL input reference clock signals, depicted as “refclkp” 220 and “refclkn” 222 from the reference clock source 108 (e.g., an external clock chip) is delivered to the PLL 106 from the phase interpolator 112. The PLL 106 then starts lock acquisition. The input reference clock signal (i.e., “refclkp” 220 and “refclkn” 222) path into the analog core of the PLL 106 proceeds through buffer “A” followed by buffer “C”. A feedback clock output from buffer “B” is not mixed with input reference clock at this point, yet. Rather, another feedback clock path is provided through buffer “D” followed by buffer “E”, which is output to the PFD 202 of the PLL 106.

The PLL 106 then locks to the frequency, e.g., after a few micro-seconds. Additionally, the enable signal 218 is asserted “high” to enable buffer “B”. When buffer “B” is enabled, the phase interpolator 112 is activated. Therefore, when there is a phase step (i.e., a period of deviation from an ideal clock) due to cycle-to-cycle jitter at the input reference clock, the phase interpolator 112 reduces the amount of the jitter by mixing (e.g., averaging) it with the feedback clock.

The amount of reference clock phase to be filtered by the phase interpolator 112 in FIG. 2 is determined by a coefficient referred to as “alpha” or “α”. For example, when alpha (i.e., α) is equal to half (i.e., 0.5), the phase interpolator 112 blends half of the reference clock phase with half of the feedback clock. When there is a 100 ps input reference clock phase step provided into buffer “A”, for instance, the phase interpolator 112 reduces it to 50 ps since half of the input reference clock information is passed into the PLL. When alpha (i.e., α) is equal to one, the phase mixer circuit disregards the feedback clock. Therefore, when there is a 100 ps input reference clock phase step provided to buffer “A”, the phase interpolator 112 passes the signal straight to the PLL 106 unattenuated, i.e., the signal is not processed by the phase interpolator 112. Thus, in this example, a similar situation is presented as if the phase interpolator 112 was not included in the system 200.

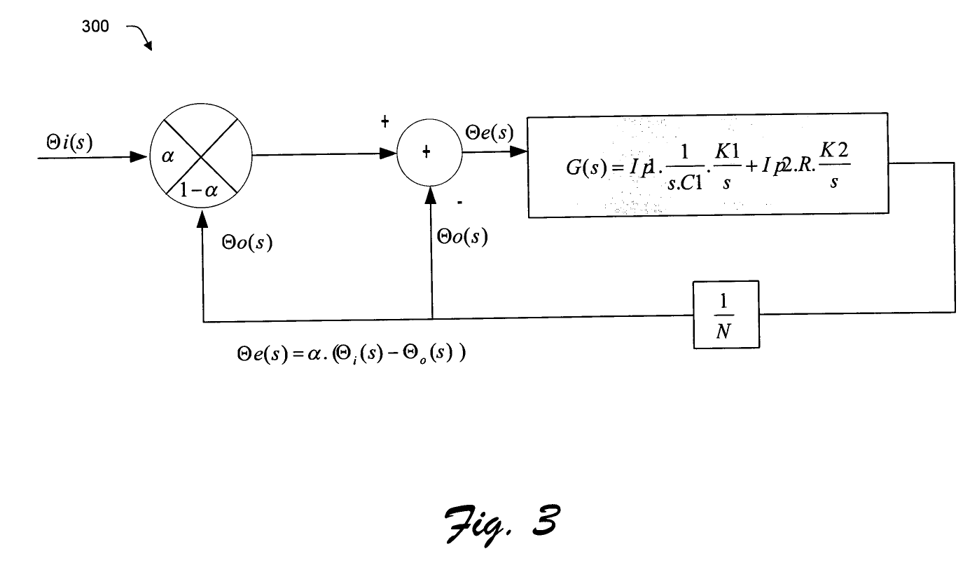

FIG. 3 illustrates an exemplary implementation showing a self-biased second-order PLL model 300 that incorporates a phase interpolator. Modeling has shown that by setting alpha less than or equal to one, PLL 106 bandwidth may be lowered to meet desired bandwidth target. For example, a transfer function of a self-biased 2^{nd} order PLL model may be described as follows:

$$H ( s ) = \frac{Θ o ( s )}{Θ i ( s )} = \frac{2 \cdot ς \cdot Wn \cdot s + {Wn}^{2}}{{s}^{2} + 2 \cdot ς \cdot Wn \cdot s + {Wn}^{2}}$$

The transfer function may also be written in terms of G(s) as shown below:

$$\begin{matrix}H ( s ) = \frac{Θ o ( s )}{Θ i ( s )} \\ = \frac{2 \cdot ς \cdot Wn \cdot s + {Wn}^{2}}{{s}^{2} + 2 \cdot ς \cdot Wn \cdot s + {Wn}^{2}} \\ = \frac{G ( s )}{G ( s ) + N} \\ where G ( s ) = [ \frac{2 \cdot ς \cdot Wn}{s} + \frac{{Wn}^{2}}{{s}^{2}} ] \cdot N\end{matrix}$$

In simulations (e.g., MatLab), this can be expressed as follows:
Num=[02.ζ.Wn.NN.Wn²]
Denom=[N 2.ζ.Wn.NN.Wn²]
H(s)=tƒ(Num, Denom)

The PLL model 300 of FIG. 3 depicts the above described model as modified to include the phase interpolator. The new transfer function, Hnew(s) may be expressed as follows:

$$\begin{matrix}Θ o ( s ) = G ( s ) \cdot \frac{1}{N} \cdot Θ e ( s ) \\ Θ e ( s ) = \frac{Θ o ( s ) \cdot N}{G ( s )} \\ Θ e ( s ) = α \cdot Θ i ( s ) + ( 1 - α ) \cdot Θ o ( s ) - Θ o ( s ) \\ \frac{Θ o ( s ) \cdot N}{G ( s )} = α \cdot Θ i ( s ) + Θ o ( s ) - α \cdot Θ o ( s ) - Θ o ( s ) \\ \frac{Θ o ( s ) \cdot N}{G ( s )} = α \cdot [ Θ i ( s ) - Θ o ( s ) ] \\ Θ o ( s ) \cdot [ \frac{N}{G ( s )} + α ] = α \cdot Θ i ( s ) \\ Hnew ( s ) = \frac{Θ o ( s )}{Θ i ( s )} \\ = \frac{α}{α + \frac{N}{G ( s )}} \\ Hnew ( s ) = \frac{Θ o ( s )}{Θ i ( s )} \\ = \frac{G ( s )}{G ( s ) + \frac{N}{α} }\end{matrix}$$

In simulation, Hnew(s) may be expressed as follows:

$$\begin{matrix}Numnew = [ \begin{matrix}0 & 2 \cdot ς \cdot Wn \cdot N & N \cdot {Wn}^{2}\end{matrix} ] \\ Denomnew = [ \begin{matrix}\frac{N}{α} & 2 \cdot ς \cdot Wn \cdot N & N \cdot {Wn}^{2}\end{matrix} ] \\ Hnew ( s ) = tf ( Numnew , Denomnew\end{matrix}$$

From the equations above, it is shown that by using the phase interpolator, the phase error is scaled by alpha (α), therefore reducing cycle-to-cycle jitter output from an input reference clock, as shown in the following expression:
Θₑ(S)=α.(Θᵢ(S)−Θₒ(s))

A traditional technique which was utilized to reduce input reference clock feed-through jitter involves increasing loop filter capacitors (e.g., C1) inside the PLL analog core, which required modifying the PLL analog core and the capacitor which may consume an inordinate amount of space on an integrated circuit and is therefore costly. Another technique involved “dividing down” the input reference clock to increase the feedback divider ratio. However, dividing the input reference clock generally does not reduce feed-through transfer jitter, as may be shown in full-loop simulations. Yet another technique involves adjusting charge pump current ratios and loop resistor multiplier factor to achieve lower bandwidth. This technique, however, requires modifying existing PLL analog cores in order to lower its bandwidth.

Using the current phase integration techniques described herein, however, less additional hardware is used, thereby allowing it to be used with current PLL architectures as well as conserving space on the integrated circuit. For example, the phase integrated may be implemented using five tri-state inverters as shown in FIG. 2. Additionally, PLL bandwidth may be easily adjusted by setting different values of alpha, i.e., “α”, further discussion of which may be found in relation to FIG. 4. Further, the phase interpolator may be easily bypassed by disabling the “enable” signal.

FIG. 4 illustrates in exemplary schematic implementation showing the phase interpolator 112 of FIG. 2 in greater detail. As shown in FIG. 4, the feedback buffer 402 (i.e., fbclk buffer) whose output is blended with the reference clock 404 (i.e., refclk) is programmable using signals “en1”, “en1b”, “en2” and “en2b”. Additionally, the feedback (i.e., fbclk) buffer 402 strength may be adjusted to get different values of alpha, i.e., “α”. For example, if the reference clock (i.e., refclk) buffer 406 and feedback (i.e., fbclk) buffer 402 sizes are made equal, then alpha (i.e., “α”) is effectively 0.5. Thus, when there is 100 ps cycle-cycle jitter at the reference clock 404 input, the reference clock buffer 406 experiences 50 ps of cycle-cycle jitter, since α is set to 0.5.

Although these techniques have been described in relation to lower clock jitter, these techniques may be employed in any instance in which low bandwidth PLLs are desired. Additionally, these techniques are particularly useful for serial link I/O that uses forwarded clock architecture, such as PCIe and FBD2 because low short term accumulated jitter on transmit clocks is generally desired.

Exemplary Procedures

The following discussion describes phase interpolation techniques that may be implemented utilizing the previously described systems and devices. The procedures are shown as a set of blocks that specify operations performed by one or more devices and are not necessarily limited to the orders shown for performing the operations by the respective blocks.

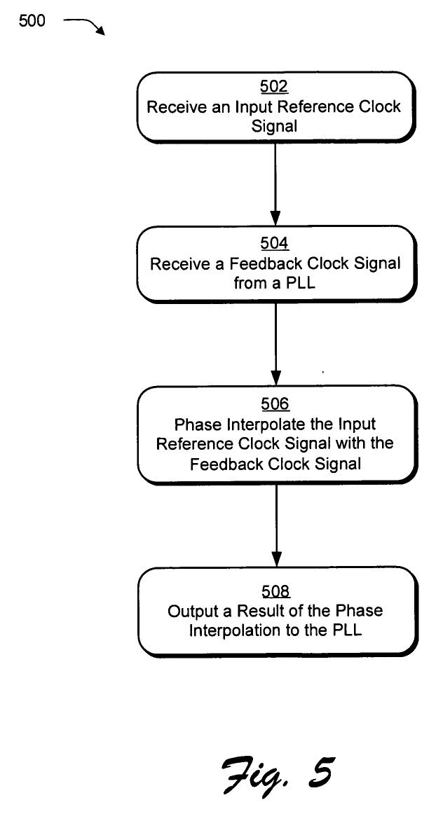

FIG. 5 depicts a procedure 500 in an exemplary implementation in which input reference clock and feedback signals are mixed to reduce bandwidth of a phase-locked loop. An input reference clock signal is received (block 502). For example, the phase interpolator 112 of FIG. 2 may receive a signal from a reference clock source 108.

A feedback clock signal is received from a PLL (block 504). The input reference clock signal is phase interpolated with the feedback clock signal (block 506). The phase interpolator 122, for instance, may phase interpolate a signal “refa” with a signal “fbka” of FIG. 2 to generate signals “refb” and “fbkb”. A result of the phase interpolation is then output to the PLL (block 508).

Conclusion

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

What is claimed is:

1. An apparatus comprising:
a phase-locked loop; and
a phase interpolator to interpolate a reference clock signal with a feedback signal from the phase-locked loop to reduce bandwidth of the phase-locked loop.

2. An apparatus as described in claim 1, wherein the phase interpolator is to output the interpolated signal and the feedback signal to a phase frequency detector of the phase-locked loop.

3. An apparatus as described in claim 2, wherein the phase frequency detector is to control a voltage-controlled oscillator of the phase-locked loop.

4. An apparatus as described in claim 1, wherein the phase interpolator is to interpolate a variable amount of reference clock signal with the feedback signal.

5. An apparatus as described in claim 1, wherein the phase interpolator is to be activated or bypassed through use of an enable signal.

6. An apparatus as described in claim 5, wherein the enable signal is a sticky-lock signal.

7. An apparatus as described in claim 1, wherein the phase interpolator is implemented as a digital-type phase mixer.

8. An apparatus as described in claim 1, wherein the phase interpolator is implemented using at least five buffers.

9. An apparatus comprising a phase interpolator to mix a signal from a reference clock source with a feedback signal from the phase-locked loop to control bandwidth of a phase-locked loop.

10. An apparatus as described in claim 9, wherein the phase interpolator is to output the interpolated signal and the feedback signal to a phase frequency detector of the phase-locked loop.

11. An apparatus as described in claim 10, wherein the phase frequency detector is to control a voltage-controlled oscillator of the phase-locked loop.

12. An apparatus as described in claim 9, wherein the phase interpolator is to interpolate a variable amount of the signal from the reference clock with the feedback signal.

13. An apparatus as described in claim 9, wherein the phase interpolator is to be activated or bypassed through use of an enable signal from the phase-locked loop.

14. A system comprising:
an integrated circuit having a phase-locked loop and a phase interpolator to interpolate a reference clock signal with a feedback signal from the phase-locked loop to reduce bandwidth of the phase-locked loop; and
a wireless interface communicatively coupled to an output of the integrated circuit.

15. A system as described in claim 14, wherein the phase interpolator is to output the interpolated signal and the feedback signal to a phase frequency detector of the phase-locked loop.

16. A system as described in claim 14, wherein the phase frequency detector is to control a voltage-controlled oscillator of the phase-locked loop.

17. A system as described in claim 14, wherein the phase interpolator is to interpolate a variable amount of reference clock signal with the feedback signal.

18. A system as described in claim 14, wherein the phase interpolator is to be activated or bypassed through use of an enable signal.

19. A method comprising:
receiving an input reference clock signal; and
phase interpolating the input reference clock signal with a feedback clock signal from a phase-locked loop.

20. A method as described in claim 19, further comprising outputting a result of the phase interpolation and the feedback clock signal to the phase-locked loop.

21. A method as described in claim 19, wherein the phase interpolating and the outputting are performed by a phase interpolator implemented using one or more integrated circuits.
